(19) United States
(12) Patent Application Publication
(10) Pub. No.: US 2013/0247935 A1
(43) Pub. Date: Sep. 26, 2013

(54) GETTER RETICLE

(71) Applicant: Seh-Jin Park, San Jose, CA (US)

(72) Inventor: Seh-Jin Park, San Jose, CA (US)

(21) Appl. No.: 13/991,621

(22) PCT Filed: Oct. 31, 2011
(86) PCT No.: PCT/US11/58640

§ 371 Date: Jun. 4, 2013

(51) Int. Cl. H01L 21/67; B08B 6/00

(52) U.S. Cl. CPC H01L 21/67017; B08B 6/00
USPC 134/1; 427/58; 15/1.51

(57) ABSTRACT

A getter layer is deposited on an electrode layer on one side of a substrate. The electrode layer is configured to provide a first electrode to hold charges in the getter layer positioned between the first electrode and a second electrode. The getter layer may include a polymer. In one embodiment, an optically dark layer in a reflection mode or in a transmission mode is deposited on other side of the substrate. In one embodiment, one or more optically reflective films are deposited on a second side of the substrate. In one embodiment, a getter reticle having a getter layer on an electrode layer on a substrate is moved toward a surface. The getter layer of the getter reticle is attached to the surface by an electrostatic force. Contaminants are transferred from the surface to the getter layer by the electrostatic force.

### FIELD

Embodiments of the present invention relate to the field of electronic device manufacturing, and in particular, to cleaning the semiconductor processing equipment.

### BACKGROUND

Many semiconductor processing systems, for example, Extreme Ultraviolet lithography (“EUVL”) steppers, plasma etchers, and deposition systems, may have a vacuum chamber and an electrostatic chuck. The electrostatic chuck is typically used for holding, for example, a photomask reticle, blank, or wafer. For example, in a EUV lithography system, the reticle or the wafer needs strong physical contact to the chuck surface to prevent from motion during scanning. Strong physical contact with the surface may result in generating residue particles and other foreign matters (“contaminants”) on the surface. The contaminants can be, for example, metal particles, metal oxide particles, and other residues. Contaminants on the surface of the chuck can cause a significant problem for the operation of the system, such as for EUV lithography printing, plasma etching, or ion beam deposition (“IBD”). Furthermore, the contaminants in the system can be transferred to other photomask reticles or wafers making the problem even worse. Currently, troubleshooting of the contaminated tools requires a lot of time and resources. Typically, such troubleshooting involves many operations, for example, de-installation of the tool, cleaning, and then re-installation of the tool. Accordingly, the cost of the troubleshooting of the contaminated semiconductor processing system is significant.

Typically, to clean the semiconductor processing system that contains contaminants, the system is taken apart. For the most semiconductor processing tools, e.g., EUV stepper, etcher, or IBD system, such cleaning requires significant amount of time and efforts. For example, if an electrostatic chuck has contamination issue, the current solution involves removing the chuck out of the vacuum chamber, and cleaning the surface of the chuck ex-situ (outside of the system). This procedure takes tremendous amount of time and cost and significantly reduces production throughput.

As described above, contamination by particles or foreign matters is one of the most significant issues in semiconductor fabrication process. As size of the features of the integrated circuits decreases, the contamination issue becomes more severe. For example, the foreign particles for the photolithography process can cause significant pattern placement error (“PPE”).

The EUVL process may target next generation lithography by using short wavelength radiation having wavelength, for example, about 13.5 nm that enables printing features having a size smaller than 22 nm half pitch (“hp”). Generally, the limit of the PPE for 21 nm hp node is about 3.6 nm. Accordingly, a particle bigger than 1-2 microns (“μm”) on a reticle back side or on a chuck may cause such PPE that is not acceptable for 21 nm hp processing. Once the surface of the chuck or wafer in the semiconductor processing system becomes contaminated, the conventional procedure requires breaking a vacuum in the system, removing the chuck or wafer from a vacuum chamber, and then wiping the surface. Such procedure is not effective and results in significant semiconductor manufacturing losses. Additionally, tacky films that may be used for removing the foreign matters leave residue on the chuck surface.

### BRIEF DESCRIPTION OF THE DRAWINGS

The present invention is illustrated by way of example and not limitation in the figures of the accompanying drawings, in which like references indicate similar elements, in which:

FIG. 1A is a cross-sectional view of a substrate to fabricate a getter reticle according one embodiment of the invention.

FIG. 1B is a view similar to FIG. 1A, after an electrode layer is deposited on insulating substrate to fabricate a getter reticle according to one embodiment of the invention.

FIG. 1C is a view similar to FIG. 1B, after a getter layer is deposited onto electrode layer to fabricate a getter reticle according to one embodiment of the invention.

FIG. 1D is a top view of an exemplary embodiment of a getter reticle, as described in FIG. 1C.

FIG. 1E is a bottom view of an exemplary embodiment of a getter reticle, as described in FIG. 1C.

FIG. 2A is a cross-sectional view of a getter reticle having an alignment pattern at a back side of a substrate according to one embodiment of the invention.

FIG. 2B is a bottom view of an exemplary embodiment of a getter reticle, as described in FIG. 2A.

FIG. 3A is a cross-sectional view of a getter reticle having one or more optically reflective films on a back side of the substrate according to one embodiment of the invention.

FIG. 3B is a bottom view of an exemplary embodiment of a getter reticle, as described in FIG. 3A.

FIG. 4A is a cross-sectional view of a getter reticle according to another embodiment of the invention.

FIG. 4B is a top view of an exemplary embodiment of a getter reticle, as described in FIG. 4A.

FIG. 4C is a bottom view of an exemplary embodiment of a getter reticle, as described in FIG. 4A.

FIG. 5A is a cross-sectional view of a getter reticle having alignment pattern features, such as a feature at a back side of a substrate according to another embodiment of the invention.

FIG. 5B is a bottom view of an exemplary embodiment of a getter reticle, as described in FIG. 5A.

FIG. 6A is a cross-sectional view of a getter reticle having one or more optically reflective films on a back side of the substrate according to another embodiment of the invention.

FIG. 6B is a bottom view of an exemplary embodiment of a getter reticle, as described in FIG. 6A.

FIG. 7A is a cross-sectional view of a getter reticle having a getter layer on an electrode layer on both sides of an insulating substrate according to another embodiment of the invention.

FIG. 7B is a cross-sectional view of a getter reticle having a getter layer directly deposited on both sides of a conducting or semiconducting substrate according to another embodiment of the invention.

FIG. 8 shows an exemplary schematic of an electrostatic apparatus and a getter reticle according to one embodiment of the invention.

FIGS. 9A-9C illustrate a method to in-situ clean a surface of an electrostatic apparatus from the contaminants using a getter reticle according to one embodiment of the invention.

FIG. 10A shows a block diagram of a semiconductor processing system to in-situ clean a surface of an electrostatic apparatus according to one embodiment of the invention.

FIG. 10B illustrates defect density maps before (a) and after (b) in-situ applying a getter reticle on an electrostatic chuck according to one embodiment of the invention.

FIG. 11A is a cross-sectional view of a getter reticle to protect an actual reticle surface from a contamination according to another embodiment of the invention.

FIG. 11B is a cross-sectional view of a getter film placed to protect an actual reticle surface from a contamination according to another embodiment of the invention.

### DETAILED DESCRIPTION

In the following description, numerous specific details, such as specific materials, dimensions of the elements, etc. are set forth in order to provide thorough understanding of one or more of the embodiments of the present invention. It will be apparent, however, to one of ordinary skill in the art that the one or more embodiments of the present invention may be practiced without these specific details. In other instances, semiconductor fabrication processes, techniques, materials, equipment, etc., have not been described in great details to avoid unnecessarily obscuring of this description. Those of ordinary skill in the art, with the included description, will be able to implement appropriate functionality without undue experimentation.

While certain exemplary embodiments of the invention are described and shown in the accompanying drawings, it is to be understood that such embodiments are merely illustrative and not restrictive of the current invention, and that this invention is not restricted to the specific constructions and arrangements shown and described because modifications may occur to those ordinarily skilled in the art.

Reference throughout the specification to “one embodiment”, “another embodiment”, or “an embodiment” means that a particular feature, structure, or characteristic described in connection with the embodiment is included in at least one embodiment of the present invention. Thus, the appearance of the phrases “in one embodiment” or “for an embodiment” in various places throughout the specification are not necessarily all referring to the same embodiment. Furthermore, the particular features, structures, or characteristics may be combined in any suitable manner in one or more embodiments.

Moreover, inventive aspects lie in less than all the features of a single disclosed embodiment. Thus, the claims following the Detailed Description are hereby expressly incorporated into this Detailed Description, with each claim standing on its own as a separate embodiment of this invention. While the invention has been described in terms of several embodiments, those skilled in the art will recognize that the invention is not limited to the embodiments described, but can be practiced with modification and alteration within the spirit and scope of the appended claims. The description is thus to be regarded as illustrative rather than limiting.

Methods and apparatuses providing a getter reticle to in-situ clean a surface in semiconductor processing systems are described herein. A getter layer is deposited on an electrode layer on one side of a substrate. The electrode layer is configured to provide a first electrode to hold charges in the getter layer positioned between the first electrode and a second electrode. The getter layer can include a polymer. The electrode layer can include one or more conducting layers, one or more semiconductor layers, or a combination thereof. The electrode layer is configured to apply the getter layer to a contaminated surface with an electrostatic force. In one embodiment, the electrostatic force is optimized to transfer contaminants from the surface to the getter layer. Without the electrode layer, a mechanical force needs to be used to apply the getter layer to a contaminated surface that requires an additional complicated tool structure that may cause a tool design issue, or a contamination issue. The electrode layer of the getter reticle, as described herein, provides very simple and effective way to apply an insulating polymer film to an electrostatic chuck surface with an optimized force.

In one embodiment, an optically dark layer in a reflection mode or in a transmission mode is deposited on other side of the substrate. In one embodiment, one or more optically reflective films are deposited on the other side of the substrate. In one embodiment, a getter reticle having a getter layer on an electrode layer on a substrate is moved toward a surface. The getter layer of the getter reticle is attached to the surface by an electrostatic force. Contaminants are transferred from the surface to the getter layer by the electrostatic force.

The methods and apparatuses described herein provide a solution to remove the contaminants, for example residue particles and foreign matters, from the semiconductor apparatus surface without taking the system apart using a getter reticle, which significantly reduces the system maintenance time, and improves the system availability. Typically, de-installation and then re-installation of the semiconductor processing system takes away tremendous amount of time and resources. An in-situ cleaning of the system using a getter reticle without taking the system apart, and without breaking a vacuum environment, as described herein, solves the contamination issue for the semiconductor processing system in very short time with minimal resources.

For example, a getter reticle, as described herein, can be used to clean any semiconductor processing system, such as a EUV lithography system, a plasma etching system, a sputtering system, a deposition system that uses an electrostatic chuck, a vacuum chamber, or both. In-situ cleaning of the semiconductor processing system provides substantial benefits by, for example, greatly reducing the system down time from about 1-2 weeks to about 1-2 hours. Furthermore, a getter reticle can be used to protect an actual reticle surface from fall-on particles or foreign matters.

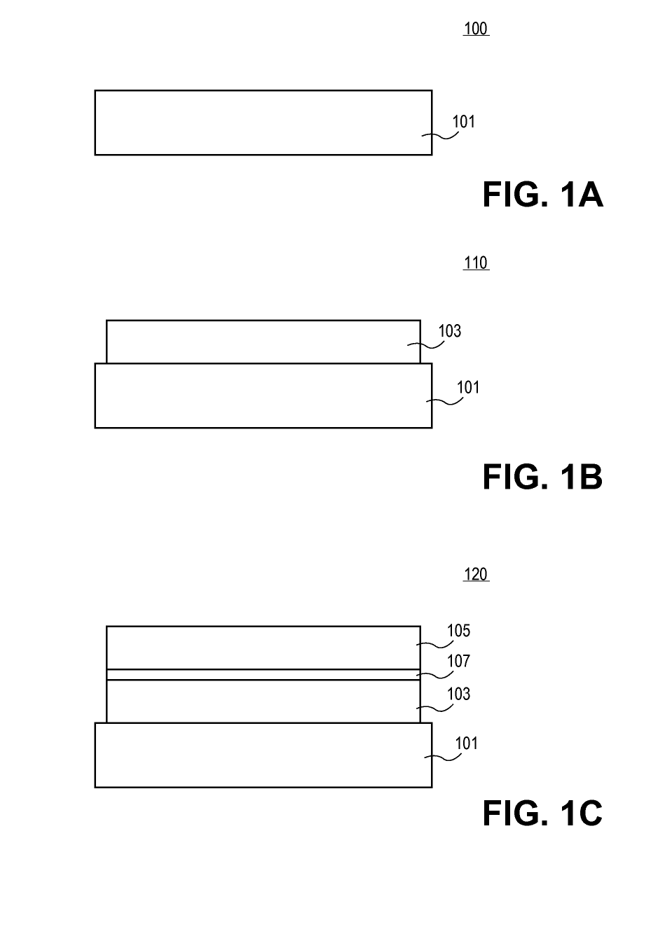

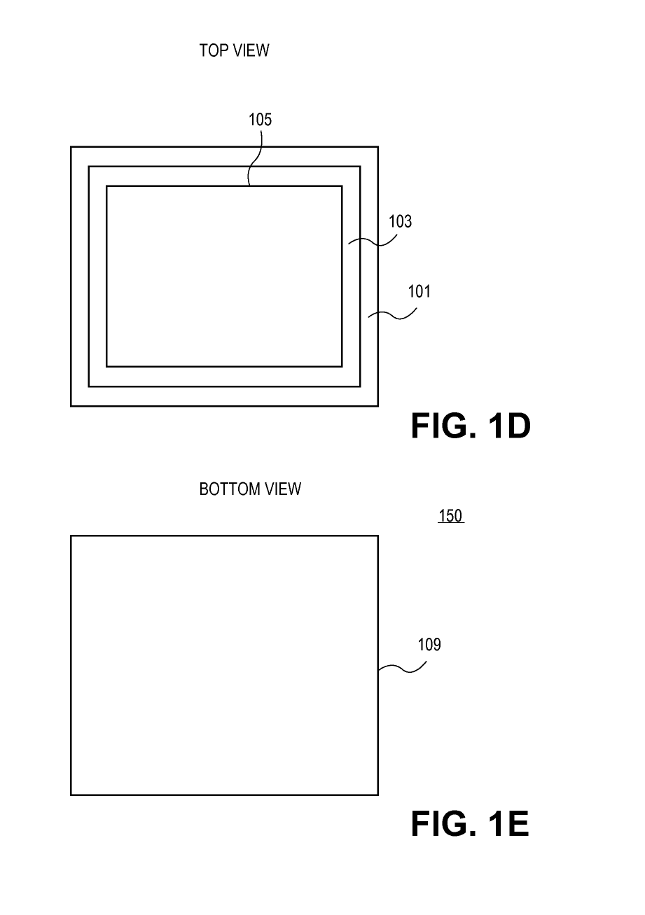

FIG. 1A is a cross-sectional view 100 of a substrate to fabricate a getter reticle according one embodiment of the invention. Typically, the substrate is insulating for photomask reticles, and semiconducting or insulating for wafers. In one embodiment, substrate 101 is made of an insulating material, for example, a silica based glass, quartz, any other dielectric material, for example, an interlayer dielectric, an oxide (e.g., silicon oxide), nitride (e.g., silicon nitride), or a combination thereof. In one embodiment, substrate 101 is a photomask substrate. In one embodiment, substrate 101 is an insulating substrate with additives to reduce thermal expansion coefficient, such as a titanium silicate glass substrate, an Ultra Low Expansion (“ULE®”) glass substrate produced by Corning, Inc, located in Corning, N.Y., or other like substrate. In one embodiment, the thickness of substrate 101 is the approximate range of about 1 mm to about 20 mm. In one embodiment, the thickness of substrate 101 is about 0.25 inches.

FIG. 1B is a view 110 similar to FIG. 1A, after an electrode layer 103 is deposited on insulating substrate 101 to fabricate a getter reticle according to one embodiment of the invention. Electrode layer 103 acts as an electrode for holding charges in a dielectric material that is positioned between electrode layer 103 and other electrode, as described in further detail below. In one embodiment, electrode layer 103 has one or more conducting layers, one or more semiconductor layers, or a combination thereof.

The electrode layer 103 can be deposited on substrate 101 using one of the techniques known to one of ordinary skill in the semiconductor manufacturing, for example, by sputtering, chemical vapor deposition (“CVD”), atomic layer deposition (“ALD”), electron beam evaporation, molecular beam epitaxy (“MBE”), and other like deposition techniques.

The electrode layer can be made of any conducting material, for example, metals, metal compounds, nitrides, oxides, oxynitrides, carbides, and other materials. For example, the conducting material for the conducting layer can be chromium (Cr), copper (Cu), ruthenium (Ru), nickel (Ni), cobalt (Co), iron (Fe), manganese (Mn), titanium (Ti), aluminum (Al), hafnium (Hf), tantalum (Ta), tungsten (W), Vanadium (V), Molybdenum (Mo), palladium (Pd), gold (Au), silver (Au), platinum Pt, or any combination thereof.

In at least some embodiments, electrode layer 103 includes one or more layers made of Cr, chromium nitride (“CrN”) titanium nitride (“TiN”), tantalum nitride (“TaN”), or any combination thereof. In one embodiment, the conducting material for electrode layer 103 is polysilicon. In one embodiment, electrode layer 103 of one or more conducting, one or more semiconducting, or a combination thereof layers has a sheet resistance that does not exceed 10⁴ Ohm/square. In at least some embodiments, the thickness of the electrode layer 103 is from about 50 nanometers (“nm”) to about 100 nm.

FIG. 1C is a view 120 similar to FIG. 1B, after a getter layer 105 is deposited onto electrode layer 103 to fabricate a getter reticle according to one embodiment of the invention. In one embodiment, getter layer 105 includes one or more polymer films. As shown in FIG. 1C, an adhesion layer 107 is formed between getter layer 103 and electrode layer 103. In at least some embodiments, the adhesion layer is applied to bond the getter layer and the electrode layer together and prevent the getter layer from peeling off the electrode layer. The getter layer can be any of thermosetting resins including an epoxy resin, a phenolic resin, a polyimide resin, a urea resin, a melanine resin, an unsaturated polyester resin, a diacryloylphthalic acid polymer resin, and other like resins, or a combination thereof. In one embodiment, getter layer 105 is polymer. In one embodiment, getter layer is made of one or more polyamide films. In one embodiment, getter layer 105 has the adhesion strength less than 0.05 Newtons (“N”)/10 millimeters (“mm”). In one embodiment, getter layer 105 includes a porous polymer layer having porosity of from about 30% to about 90%.

In at least some embodiments, the getter layer deposited on the electrode layer, e.g., one or more conducting or semiconducting layers on the substrate has one or more porous polymer films with negligible tackiness of less than about 0.05 Newtons (“N”)/10 millimeters (“mm”) to avoid leaving residue while cleaning a surface.

In at least some embodiments, getter layer 105 has the thickness from about 100 μm to about 900 μm. In at least some embodiments, getter layer 105 is mechanically placed onto electrode layer 103 using one of techniques known to one of ordinary skill in the art of semiconductor manufacturing.

As shown in FIG. 1C, a getter reticle has electrode layer 103 made of, for example, one or more conducting or semiconducting films between substrate 101 made of, for example, glass, and getter layer 105 made of one or more polymer films. The one or more conducting or semiconducting films introduced between the electrically insulating substrate and the one or more polymer films can provide electrostatic attraction force between a surface of an electrostatic chuck or any other electrostatic apparatus and a getter reticle. The one or more polymer films can be used to actually remove contaminants (e.g., foreign particles) from the surface of the electrostatic chuck or any other apparatus providing an electrostatic force. The electrode layer made of one or more conducting or semiconducting films, or bulk material having sheet resistance less than 10⁴ Ohm/sq can work as an electrode to hold charges in a dielectic layer, such as getter layer 105 that is placed adjacent to a surface of an apparatus having one or more electrodes (e.g, an electrostatic chuck). The adhesion strength between the electrode layer and the substrate is enough for them not be separated by an electrostatic chucking force. The adhesion strength between the electrode layer and the getter layer is enough for them withstand separation by an electrostatic chucking force.

FIG. 1D is a top view 140 of an exemplary embodiment of a getter reticle, as described in FIG. 1C. As shown in FIG. 1D, the getter reticle having getter layer 105 on electrode layer 103 on substrate 101 has a rectangular or square shape.

FIG. 1E is a bottom view 150 of an exemplary embodiment of a getter reticle, as described in FIG. 1C. As shown in FIG. 1E, a getter reticle 109 has a rectangular or square shape.

Conventional cleaning semiconductor wafers are circular and may not be used to in-situ clean reticle semiconductor processing systems due to the geometric difference. On the other hand, a reticle substrate (e.g., blank) may not be used for in-situ electrostatic chuck cleaning. An electrostatic force to hold the blank on the chuck cannot be generated due to the lack of electrical conductivity of the reticle substrate. In one embodiment, the getter reticle to in-situ clean a surface of the electrostatic chuck (or any other apparatus having an electrostatic force) in a vacuum chamber, as described herein, complies with dimensions requirements for automatic loading of the reticle into the semiconductor processing system (e.g., an EUVL stepper, plasma etcher, IBD, or other vacuum systems using electrostatic chuck).

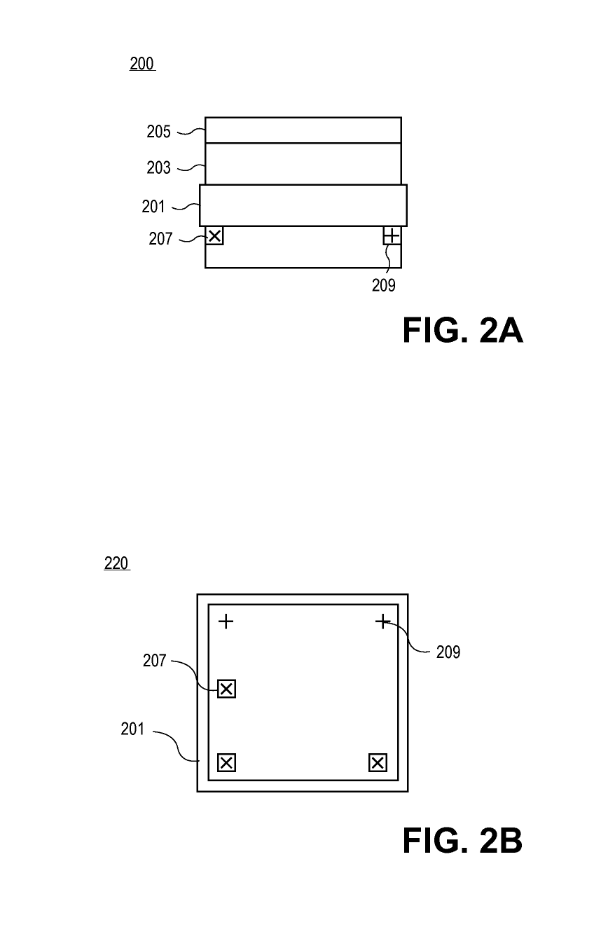

FIG. 2A is a cross-sectional view 200 of a getter reticle having an alignment pattern at a back side of a substrate according to one embodiment of the invention. As shown in FIG. 2A, the getter reticle has a getter layer 205 adjacent to an electrode layer 203 deposited on a front side of a substrate 201, as described above with respect to FIGS. 1A-1D. As shown in FIG. 2A, an optically dark layer 207 is deposited on a back side of the substrate 201. In one embodiment, a pattern having features, such as a feature 209, is formed on the back side of the substrate 201. In one embodiment, optically dark layer 207 contains one or more optically dark films in a reflection mode or in a transmission mode. The one or more optically dark films on substrate 201 can be, for example, Cr, Cr compounds, Ta, Ta compounds, W, W compounds, noble metals (Pt, Ag, Rh, etc.), noble metal compounds, etc. In one embodiment, the optically dark layer 207 contains at least one optically dark film in a reflection mode or in a transmission mode that is partially coated (patterned). In one embodiment, optically dark layer 207 is deposited onto the substrate to absorb a EUV light in a transmission mode or in a reflection mode. In one embodiment, optically dark layer 207 is a patterned layer. In one embodiment, the thickness of the optically dark layer 207 is in the approximate range of less than 50% reflectivity for a reflection mode system, or less than 10% transmittance for a transmission mode system at each actinic wavelength. In one embodiment, the pattern features, such as a feature 209, at the back side of the substrate having the optically dark layer 207 deposited thereon act as marks to align (e.g., horizontally, vertically) the getter reticle to the surface of an apparatus (e.g., an electrostatic chuck, or any other apparatus having an electrostatic force). In one embodiment, optically dark layer 207 is a photomask layer. The optically dark layer can be deposited onto the substrate using one of techniques known to one of ordinary skill in the art of semiconductor manufacturing. In one embodiment, optically dark layer 207 acts as an absorber of the EUV light to align the getter reticle to the surface that needs to be cleaned.

FIG. 2B is a bottom view 220 of an exemplary embodiment of a getter reticle, as described in FIG. 2A. In one embodiment, the getter reticle having optically dark layer 207 on a back side of substrate 201 has a rectangular or square shape to comply with dimensions requirements for automatic loading of the photomask reticle into the semiconductor processing system (e.g. an EUVL stepper, plasma etcher, IBD, or other vacuum systems using electrostatic chuck).

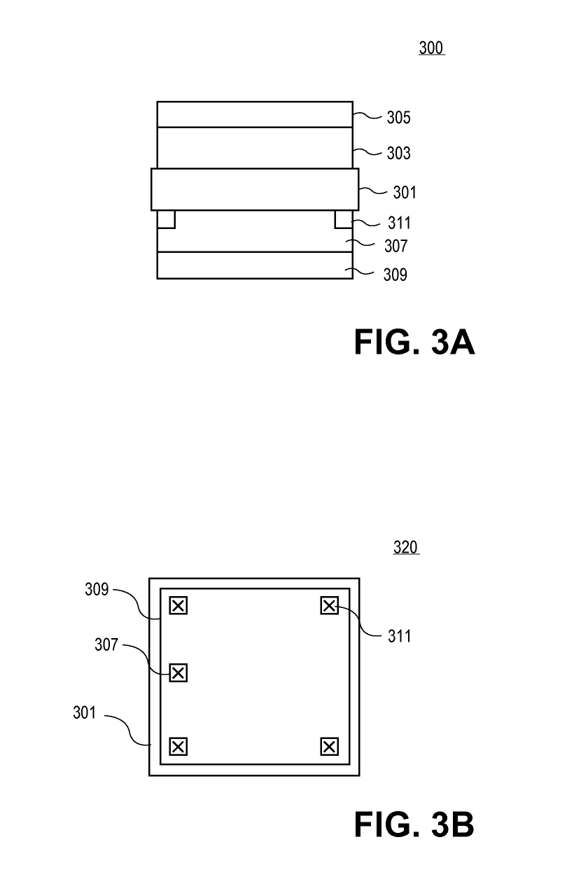

FIG. 3A is a cross-sectional view 300 of a getter reticle having one or more optically reflective films on a back side of the substrate according to one embodiment of the invention. As shown in FIG. 3A, a getter layer 305 is deposited adjacent to an electrode layer 303 on a front side of a substrate 301, as described above, and one or more optically reflective films 307 on a back side of the substrate. As shown in FIG. 3A, an optically dark layer 309 is deposited on one or more optically reflective films 307. Optically dark layer 309 can be, for example, the optically dark layer, as described with respect to FIGS. 2A and 2B.

In one embodiment, one or more optically reflective films 307 include a layer of one material and a layer of another material formed in alternating order on the substrate 301. In one embodiment, the one or more optically reflective films include a layer made of silicon and a layer made of a metal, for example, molybdenum (“Mo”), nickel (“Ni”), titanium (“Ti”), cobalt (“Co”), or any combination thereof that are formed in alternating order on the substrate. In one embodiment, the thickness of each of the layers is in the approximate range of 1 nm to 300 nm. In one embodiment, one or more optically reflective films 307 are deposited onto the substrate to reflect a EUV light to improve aligning of the getter reticle to a surface of the apparatus (e.g., electrostatic chuck, or any other apparatus providing an electrostatic force) based on the pattern features, such as a feature 311, at the back side of the substrate 301 that mimics a real photomask reticle and complies with reticle loading requirements of the semiconductor processing system (e.g., an EUVL stepper, plasma etcher, IBD, or other vacuum systems using electrostatic chuck). The one or more optically reflective films can be deposited onto the substrate using one of techniques known to one of ordinary skill in the art of semiconductor manufacturing. The optically dark layer can be deposited onto the one or more optically reflective films using one of techniques known to one of ordinary skill in the art of semiconductor manufacturing.

FIG. 3B is a bottom view 320 of an exemplary embodiment of a getter reticle, as described in FIG. 3A. As shown in FIG. 3B, the getter reticle having optically dark layer 309 on one or more optically reflective films 307 on a back side of substrate 301 has a rectangular or square shape to comply with dimensions requirements for automatic reticle loading in the semiconductor processing system (e.g., an EUVL stepper, plasma etcher, IBD, or other vacuum systems using electrostatic chuck).

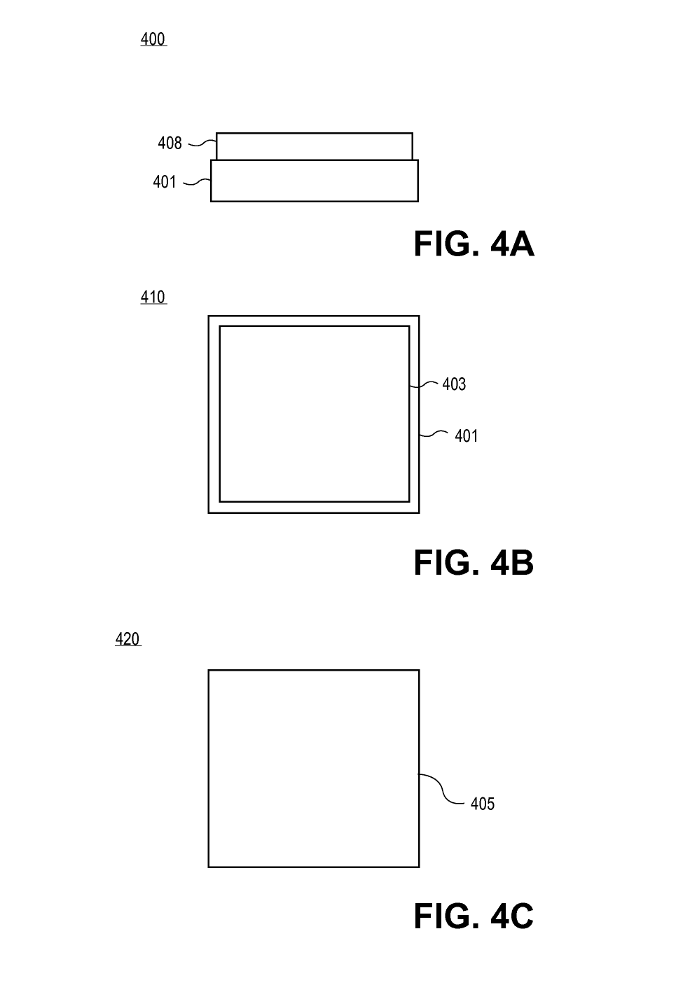

FIG. 4A is a cross-sectional view 400 of a getter reticle according to another embodiment of the invention. As shown in FIG. 4A, a getter layer 403 is directly deposited onto a 401. In one embodiment, substrate 401 has one or more conducting layers, one or more semiconductor layers, or a combination thereof. In one embodiment, substrate 401 includes a semiconductor, e.g., silicon, germanium, or any other semiconductor, having a sheet resistance that does not exceed 10⁴ Ohm/square. In at least some embodiments, substrate 101 comprises any material to make any of integrated circuits, passive (e.g., capacitors, inductors) and active (e.g., transistors, photo detectors, lasers, diodes) microelectronic devices. Substrate 401 may include insulating (e.g., dielectric) materials that separate such active and passive microelectronic devices from a conducting layer or layers that are formed on top of them. In one embodiment, substrate 101 is a monocrystalline silicon (“Si”) substrate that includes one or more dielectric layers e.g., silicon dioxide, silicon nitride, sapphire, and other dielectric materials.

In one embodiment, substrate 401 includes a conducting material having a sheet resistance that does not exceed 10⁴ Ohm/square. The conducting material can be, for example, polysilicon, metal, metal compounds, nitrides, oxides, oxynitrides, carbides, and other conducting materials. In one embodiment, the conductive material is a metal, for example, copper (Cu), ruthenium (Ru), nickel (Ni), cobalt (Co), chromium (Cr), iron (Fe), manganese (Mn), titanium (Ti), aluminum (Al), hafnium (Hf), tantalum (Ta), tungsten (W), Vanadium (V), Molybdenum (Mo), palladium (Pd), gold (Au), silver (Au), platinum Pt, or any combination thereof. In at least some embodiments, the conducting material includes Cr, chromium nitride (“CrN”), titanium nitride (“TiN”), tantalum nitride (“TaN”), or any combination thereof. In one embodiment, the thickness of substrate 401 is the approximate range of about 1 mm to about 20 mm. In one embodiment, the thickness of substrate 401 is about 0.25 inches. In one embodiment, at least a portion of the substrate 401 acts as an electrode for holding charges in a dielectric material that is positioned between electrode layer 103 and other electrode, as described in further detail below.

As shown in FIG. 4A, a getter layer 403 is deposited on conducting substrate 401. In one embodiment, an adhesion layer (not shown) is formed between getter layer 403 and substrate 401. In at least some embodiments, the adhesion layer is applied to bond the getter layer and the substrate together and prevent the getter layer from peeling off the substrate. The getter layer 403 can be, for example, a getter layer 105, as described in FIG. 1C. In at least some embodiments, getter layer 403 is mechanically placed onto substrate 401 using one of techniques known to one of ordinary skill in the art of semiconductor manufacturing.

In one embodiment, substrate 401 provides electrostatic attraction force between a surface of an electrostatic chuck (or any other electrostatic apparatus) and a getter reticle. Getter layer 403 is used to actually remove contaminants (e.g., foreign particles) from the surface of the electrostatic chuck (or any other apparatus providing an electrostatic force), as described above. In one embodiment, substrate 401 works as an electrode to hold charges in getter layer 403 placed adjacent to a surface of the apparatus having one or more electrodes (e.g., an electrostatic chuck). The adhesion strength between the getter layer and the substrate is enough to withstand separation by an electrostatic chucking force.

FIG. 4B is a top view 410 of an exemplary embodiment of a getter reticle, as described in FIG. 4A. As shown in FIG. 4B, the getter reticle having getter layer 403 on substrate 401 has a rectangular or square shape.

FIG. 4C is a bottom view 420 of an exemplary embodiment of a getter reticle, as described in FIG. 4A. As shown in FIG. 4C, a getter reticle 405 has a rectangular or square shape to comply with dimensions requirements for automatic reticle loading into the semiconductor processing system, as described above.

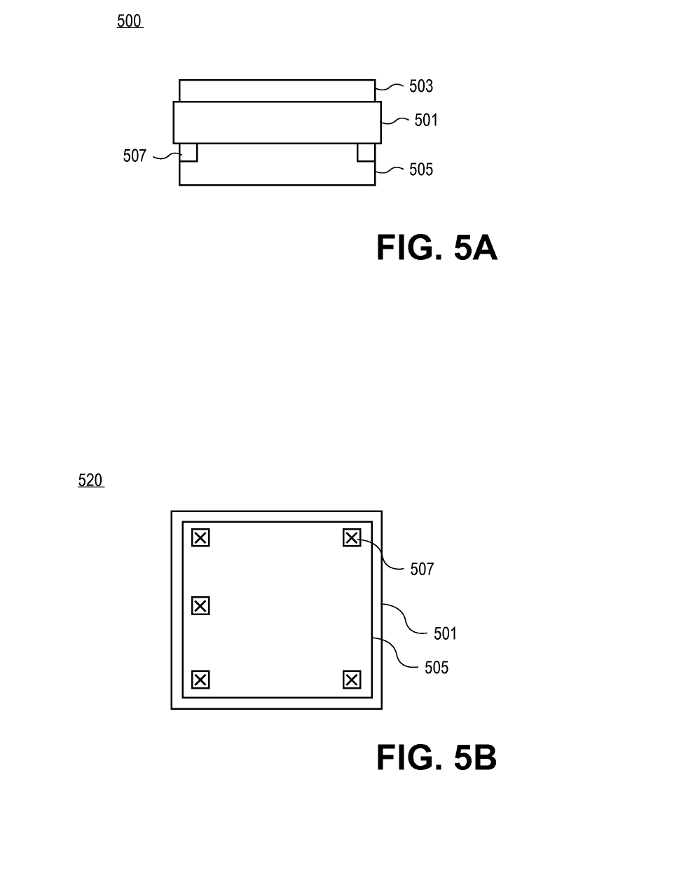

FIG. 5A is a cross-sectional view 500 of a getter reticle having alignment pattern features, such as a feature 507 at a back side of a substrate according to another embodiment of the invention. As shown in FIG. 5A, the getter reticle has a getter layer 503 directly deposited on a front side of a conducting or semiconducting substrate 501, as described above with respect to FIGS. 4A-4B. As shown in FIG. 5A, an optically dark layer 505 in a reflection mode or in a transmission mode is deposited on a back side of the substrate 501. In one embodiment, a pattern having features, such as a feature 507, is formed on the back side of the substrate 501. The optically dark layer 505 can be, for example, an optically dark layer 207, as described in FIG. 2A. In one embodiment, optically dark layer 505 is deposited onto substrate 501 to absorb a EUV light in a transmission mode or in a reflection mode. In one embodiment, optically dark layer 505 is a patterned layer. In one embodiment, pattern features, such as feature 507 at the back side of the substrate having the optically dark layer 505 deposited thereon act as marks to align (e.g., horizontally, vertically) the getter reticle to the surface of an apparatus (e.g., an electrostatic chuck, or any other apparatus having an electrostatic force). In one embodiment, optically dark layer 505 is a photomask layer. The optically dark layer can be deposited onto the substrate using one of techniques known to one of ordinary skill in the art of semiconductor manufacturing.

FIG. 5B is a bottom view 520 of an exemplary embodiment of a getter reticle, as described in FIG. 5A. In one embodiment, the getter reticle having optically dark layer 505 on a back side of substrate 501 has a rectangular or square shape to comply with dimensions requirements for automatic loading of the photomask reticle into the semiconductor processing system (e.g. an EUVL stepper, plasma etcher, IBD, or other vacuum systems using electrostatic chuck).

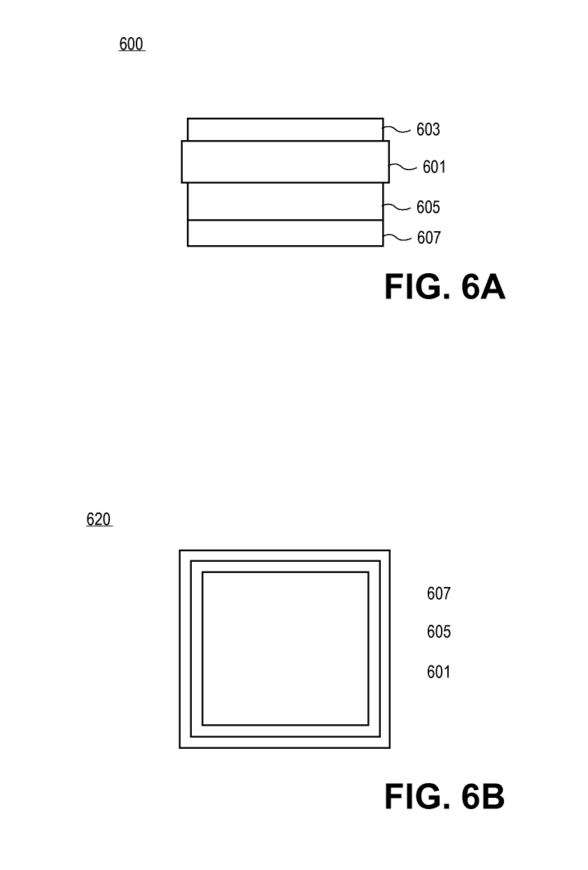

FIG. 6A is a cross-sectional view 600 of a getter reticle having one or more optically reflective films on a back side of the substrate according to another embodiment of the invention. As shown in FIG. 5A, the getter reticle has a getter layer 603 directly deposited on a front side of a conducting or semiconducting substrate 601, as described above with respect to FIGS. 4A-4B. As shown in FIG. 6A, one or more optically reflective films 605 are deposited on a back side of the substrate 601. The one or more optically reflective films 605 can be, for example one or more optically reflective films 307, as described in FIGS. 3A and 3B. As shown in FIG. 6A, an optically dark layer 607 is deposited on one or more optically reflective films 607. Optically dark layer 309 can be, for example, the optically dark layer 505, as described with respect to FIGS. 5A and 5B.

In one embodiment, one or more optically reflective films 605 are deposited onto the substrate 601 to reflect a EUV light, and to align the getter reticle to a surface of the apparatus (e.g., electrostatic chuck, or any other apparatus providing an electrostatic force) mimicking a real photomask reticle to comply with reticle loading requirements of the semiconductor processing system (e.g., an EUVL stepper, plasma etcher, IBD, or other vacuum systems using electrostatic chuck). The one or more optically reflective films can be deposited onto the conducting or semiconducting substrate using one of techniques known to one of ordinary skill in the art of semiconductor manufacturing. The optically dark layer can be deposited onto the one or more optically reflective films using one of techniques known to one of ordinary skill in the art of semiconductor manufacturing.

FIG. 6B is a bottom view 620 of an exemplary embodiment of a getter reticle, as described in FIG. 6A. As shown in FIG. 6B, the getter reticle having optically dark layer 607 on one or more optically reflective films 605 on a back side of conducting or semiconducting substrate 601 has a rectangular or square shape to comply with dimensions requirements for automatic reticle loading in the semiconductor processing system (e.g., an EUVL stepper, plasma etcher, IBD, or other vacuum systems using electrostatic chuck).

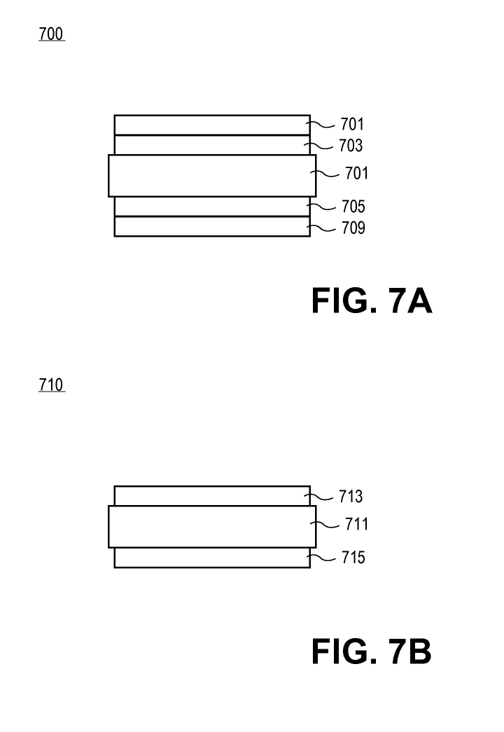

FIG. 7A is a cross-sectional view 700 of a getter reticle having a getter layer on an electrode layer on both sides of an insulating substrate according to another embodiment of the invention. The getter reticle has a getter layer 701 adjacent to an electrode layer 703 deposited on a front side of an insulating substrate 701, as described above with respect to FIGS. 1A-1D. The electrode layer 703 is configured to provide a first electrode to hold charges in the getter layer 701 positioned between the electrode layer 703 and a surface of an apparatus having one or more electrodes (not shown), as described in further detail below.

In one embodiment, an adhesion layer (not shown) is formed between getter layer 701 and electrode layer 703, as described in FIG. 1C. As shown in FIG. 7A, the getter reticle has a getter layer 709 on an electrode layer 705 that is deposited on a back side of the substrate 701. Depositing of a getter layer on a electrode layer on a substrate is described above with respect to FIGS. 1A-1B. The electrode layer 705 is configured to hold charges in the getter layer 709 positioned between the electrode layer 705 and a surface of an apparatus having one or more second electrodes (not shown), as described in further detail below.

In one embodiment, the getter reticle has a rectangular or square shape to comply with dimensions requirements for automatic loading of the photomask reticle into the semiconductor processing system (e.g., an EUVL stepper, plasma etcher, IBD, or other vacuum systems using electrostatic chuck), as described above. A getter layer on an electrode layer on each of the sides the insulating substrate can be used to clean a surface of the apparatus with an electrostatic force.

FIG. 7B is a cross-sectional view 710 of a getter reticle having a getter layer directly deposited on both sides of a conducting or semiconducting substrate according to another embodiment of the invention. The getter reticle has a getter layer 713 deposited on a front side of the conducting or semiconducting substrate 711, as described above with respect to FIGS. 4A-4C. At least a front portion of the conducting or semiconducting substrate 711 is configured to hold charges in the getter layer 713 positioned between the substrate 711 and a surface of an apparatus having one or more second electrodes (not shown), as described in further detail below.

In one embodiment, an adhesion layer (not shown) is formed between getter layer 713 and substrate 711, as described in FIG. 4A. As shown in FIG. 7B, the getter reticle has a getter layer 715 deposited on a back side of the substrate 711. Depositing of a getter layer directly on a conducting or semiconducting substrate is described above with respect to FIGS. 4A-4C.

At least a back portion of the conducting or semiconducting substrate 711 is configured to hold charges in the getter layer 715 positioned between the substrate 711 and a surface of an apparatus having one or more second electrodes (not shown), as described in further detail below. In one embodiment, the getter reticle has a rectangular or square shape to comply with dimensions requirements for automatic loading of the photomask reticle into the semiconductor processing system (e.g., an EUVL stepper, plasma etcher, IBD, or other vacuum systems using electrostatic chuck), as described above. A getter layer on each of the sides the conducting or semiconducting substrate can be used to clean a surface of the apparatus with an electrostatic force.

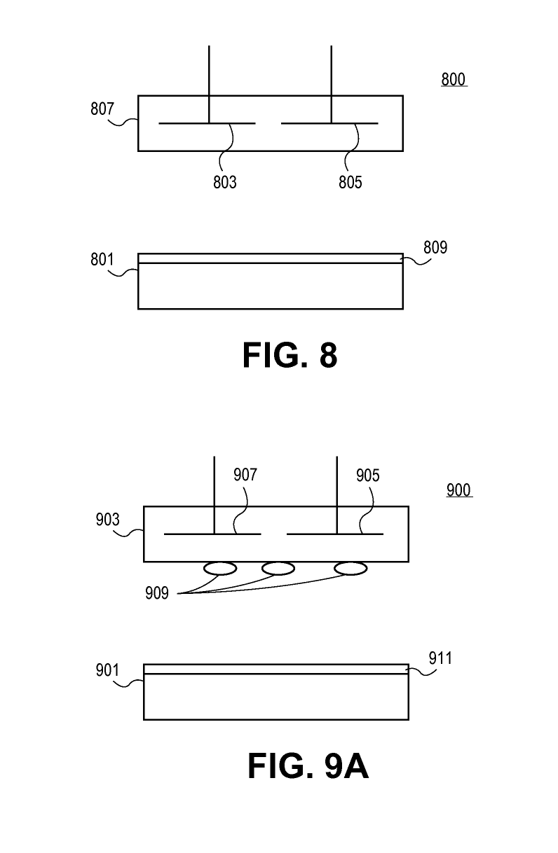

FIG. 8 shows an exemplary schematics of an electrostatic apparatus and a getter reticle according to one embodiment of the invention. As shown in FIG. 8, an electrostatic apparatus 807 has electrodes, such as an electrode 805 and an electrode 803. Electrostatic apparatus 807 can be an electrostatic chuck, or any other apparatus that provides an electrostatic force to hold objects. Getter reticle 802 can be located parallel to the surface 811.

As shown in FIG. 8, a getter reticle 801 has a getter layer 809 facing a surface 811 of the apparatus. Getter reticle 801 can be any of getter reticles described above. In one embodiment, getter reticle 801 has a getter layer 809 on an electrode layer on an insulating substrate, as described above. In one embodiment, getter reticle 801 has a getter layer 809 directly deposited onto conducting or semiconducting, as described above. In one embodiment, a getter layer of the getter reticle as described herein can be attached to the surface of the apparatus by an electrostatic force generated between the electrode layer of the getter reticle and one or more electrodes of the apparatus. In one embodiment, a getter layer of the getter reticle as described herein can be attached to the surface of the apparatus by an electrostatic force generated between the conductive or semiconductive substrate of the getter reticle and one or more electrodes of the apparatus.

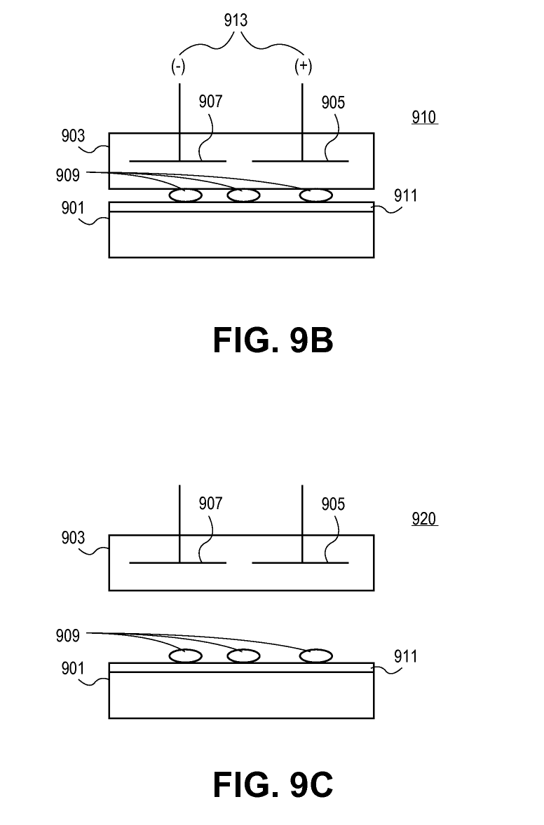

FIGS. 9A-9C illustrate a method to in-situ clean a surface of an electrostatic apparatus from the contaminants using a getter reticle according to one embodiment of the invention. As shown in a view 900 of FIG. 9A, an electrostatic apparatus 903 has electrodes, such as an electrode 905 and an electrode 907. Electrostatic apparatus 903 can be an electrostatic chuck, or any other apparatus that provides an electrostatic force to hold objects. As shown in FIG. 9A, contaminants 909, for example residue particles and foreign matters, are located on the surface of the apparatus 903. As shown in FIG. 9A, a getter reticle 901 having a getter layer 911 as described herein is moved toward a surface of the electrostatic apparatus 903. In one embodiment, the apparatus 903 is moved toward getter reticle 901. In one embodiment, getter reticle 901 is moved toward apparatus 903. In yet another embodiment, getter reticle 901 and apparatus 903 are moved toward each other. The getter reticle 901 is aligned parallel to the apparatus 903. The getter reticle can be aligned in a horizontal and vertical direction parallel to the apparatus 903 using, for example, a pattern features (not shown) on a back side of the substrate, as described herein. As shown in a view 910 of FIG. 9B, the getter layer 911 faces toward the electrostatic chuck surface. Next, the getter layer of the getter reticle is attached to the surface of the electrostatic apparatus by an electrostatic force, as described herein.

The getter layer 911 of the getter reticle 901 is strongly engaged with the surface by an electrostatic force, as shown in FIG. 9B. The electrostatic force can be generated by applying a voltage 913 to the electrodes, such as electrode 905 and electrode 907. The electrostatic force is optimized to be strong enough to at least overcome the getter reticle weight gravity. In one embodiment, the electrostatic force is optimized by adjusting the voltage applied to the electrodes. The getter layer 911 can be attached to the surface with the electrostatic force generated by applying a voltage to the electrodes. Contaminants 909 on the chuck surface are squeezed, embedded in or adhered on the polymeric surface by applying an electrostatic force between the chuck apparatus and the reticle for a predetermined time, as shown in FIG. 9B.

Next, the contaminants 909 are removed from the surface of the apparatus 903, and the getter reticle is detached from the surface. The contaminants 909 are transferred to the getter polymer layer 911, as shown in a view 920 of FIG. 9C. Particles or foreign matters are transferred from the chuck surface to the getter reticle surface, and are completely removed from the chuck surface after the getter reticle moves away from the chuck apparatus.

In alternate embodiments, the getter reticle can be detached from the surface by reducing a voltage applied to the electrodes 907 and 905, changing a polarity of the voltage, or turning the voltage off. When the electrostatic force is turned off, the getter reticle will be detached from the chuck surface, and the foreign matters will be removed from the chuck surface as well.

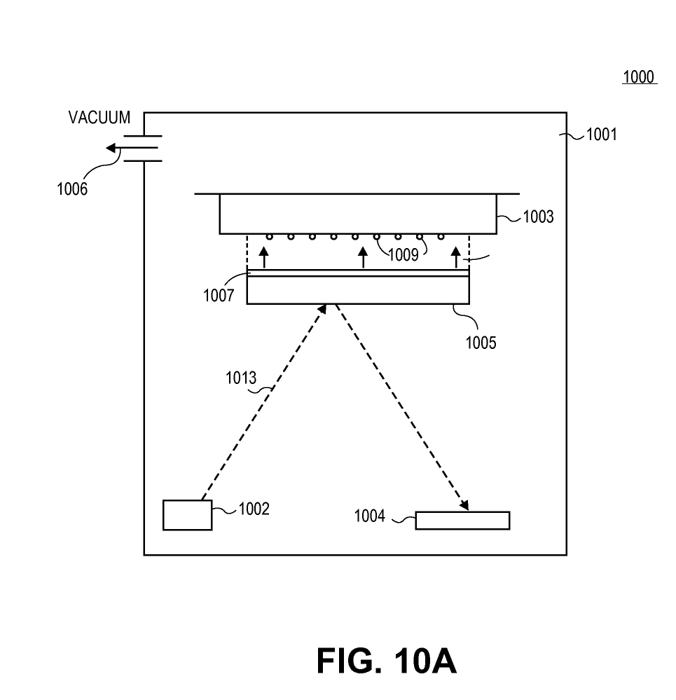

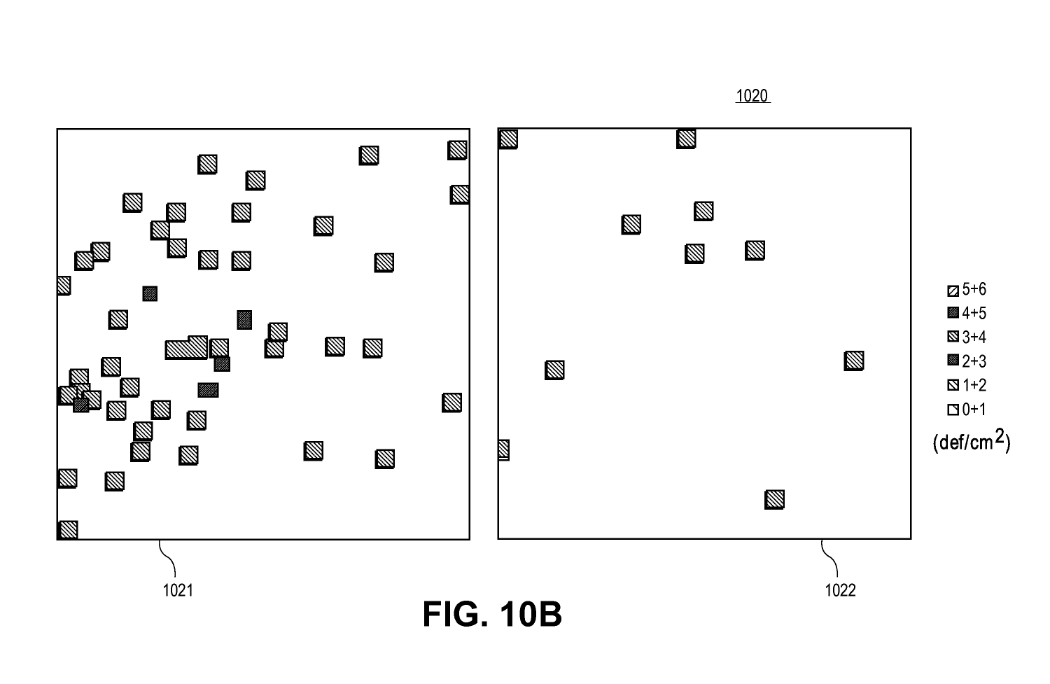

FIG. 10A shows a block diagram of a semiconductor processing system 1000 to in-situ clean a surface of an electrostatic apparatus according to one embodiment of the invention. As shown in FIG. 10A, the system 1000 has an vacuum chamber 1001. Vacuum chamber 1001 has an outlet 1006 connected to a vacuum pump system (not shown) to evacuate the air including volatile compounds produced during semiconductor processing. Vacuum chamber 1001 has an electrostatic apparatus 1003 having a surface to which a getter reticle 1005 is attached using an electrostatic force 1011, as described herein. Typically, the peak-to-valley value indicating the flatness of the surface of the electrostatic chuck is less than 30 nm to hold a bowed reticle as flat as possible in a vacuum chamber. Typically, the chuck surface and the reticle back side are fully contacted to transfer the chuck flatness to the reticle. Accordingly, maintaining the cleanliness of an electrostatic chuck is as important as a reticle surface.

Vacuum chamber 1001 has a wafer holder 1004, and an EUV source 1002. Reticle 1005 is aligned to surface of the chuck 1003 using the features of the pattern (not shown) on the back side of the substrate and EUV light 1013, as described herein. In one embodiment, the system 1000 is an EUVL stepper, plasma etcher, IBD, or other vacuum systems using electrostatic chuck system. In one embodiment, the system is an EUVL stepper and getter reticle 1005 replaces an actual photomask reticle on the surface of the electrostatic chuck.

Contaminants 1009 on the chuck surface are squeezed, embedded in or adhered on the polymeric surface by electrostatic force 1011 between the chuck apparatus and the getter reticle 1005, removed from the surface of the apparatus 1003, and the getter reticle is detached from the apparatus 1003, as described above. Electrostatic force 1011 is generated by applying a voltage to the electrodes (not shown) typically located in an electrostatic chuck fixture. The getter reticle 1005 can be removed from the chuck apparatus 1003 by turning a voltage applied to the electrodes of the electrostatic chuck off, changing the direction of the force (e.g., by changing the polarity of the voltage) while maintaining the vacuum environment in the chamber 1001. Contaminants from the surface of the chuck apparatus are transferred to the getter reticle. The getter reticle provides an advantage of cleaning off any foreign matter from the semiconductor apparatus (electrostatic chuck) surface in-situ, avoiding taking the tool or apparatus apart, and breaking vacuum environment. Additionally advantage of cleaning the electrostatic chuck using the getter reticle as described herein is that the cleaning does not require additional equipment because the existing electrostatic chuck can provide all the required performance and capability.

FIG. 10B is a view 1020 illustrating defect density maps before (a) and after (b) in-situ applying a getter reticle on an electrostatic chuck according to one embodiment of the invention. As shown in FIG. 10B, the defect density are reduced by about a factor of 5× after using the getter reticle having a silica based glass which is electrically insulating. This verifies that the getter reticle having a conducting or semiconducting layer between the insulating substrate and a getter layer, as described herein, provides enough electrostatic force to remove particles or foreign matters from the electrostatic chuck surface.

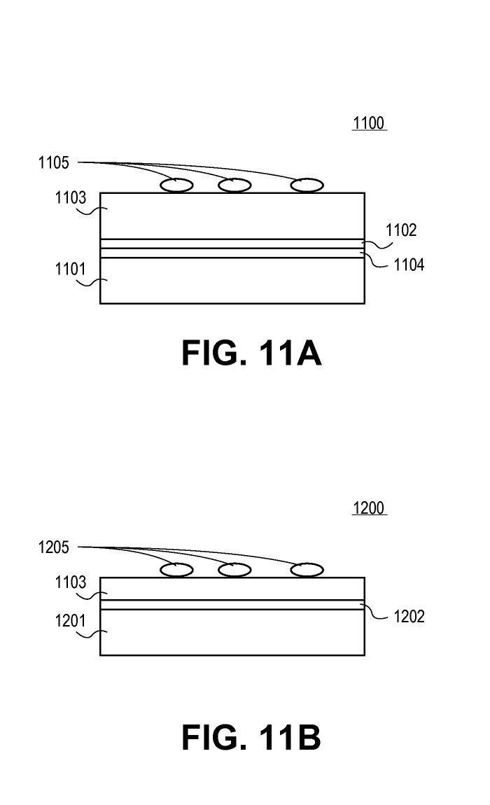

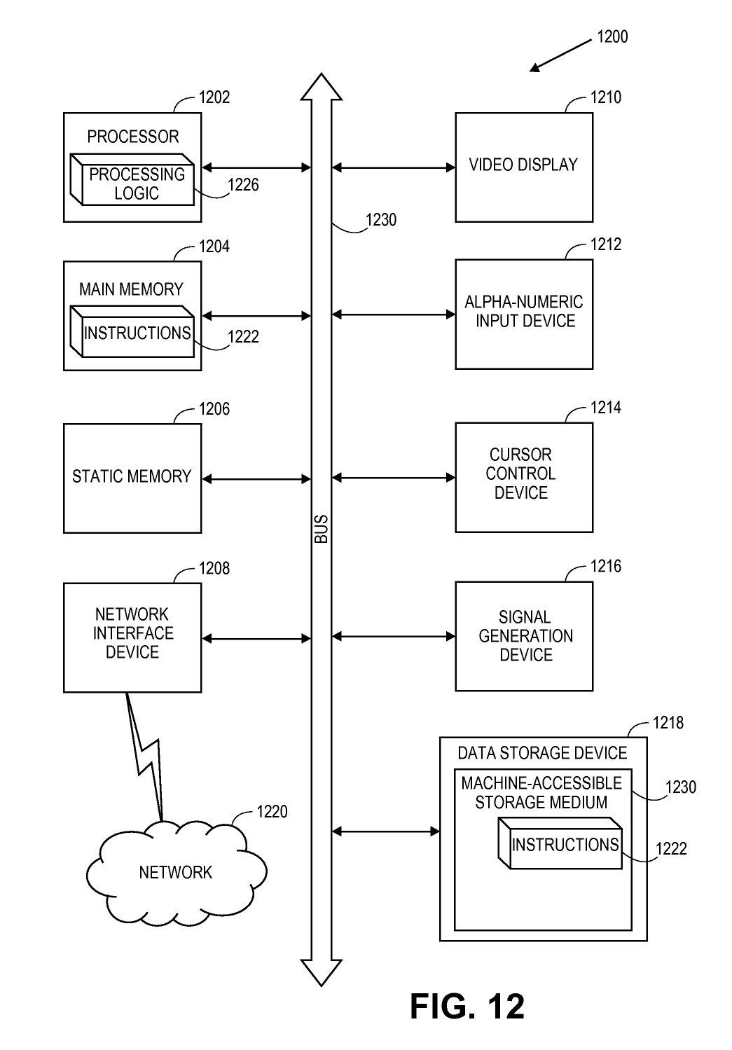

FIG. 11A is a cross-sectional view 1100 of a getter reticle used to protect an actual reticle surface from additional contamination according to another embodiment of the invention. As shown in FIG. 11A, a getter reticle 1103 having a getter layer 1102, as described herein is attached to a backside film 1104 of an actual EUV photomask reticle 1101 to protect the back side of actual photomask reticle 1101 from any falling on contaminants 1105, such as particles or foreign matters. As shown in FIG. 11B, a getter polymer layer 1203, as described herein is directly placed on a backside film 1202 of the actual photomask reticle 1201 to protect the back side of actual photomask reticle 1201 from any falling on contaminants 1205, such as particles or foreign matters. Because a getter polymer layer does not leave a residue, the getter polymer layer can be attached to the backside film of an actual reticle during reticle shipping, handling and storage to protect from falling on any contaminants.

FIG. 12 shows a block diagram of an exemplary embodiment of a data processing system 1200 to control an in-situ cleaning a surface of an electrostatic apparatus using a getter reticle according to one embodiment of the invention. The semiconductor processing system, for example, semiconductor processing system 1000, can be connected to a data processing system, for example, data processing system 1200. In at least some embodiments, the data processing system controls the semiconductor processing system to perform operations involving moving a getter reticle toward a surface, aligning the getter reticle to the surface, attaching the getter layer to the surface by an electrostatic force, removing foreign residues from the surface, and detaching the getter reticle from the surface, as described herein.

In alternative embodiments, the data processing system may be connected (e.g., networked) to other machines in a Local Area Network (LAN), an intranet, an extranet, or the Internet. The data processing system may operate in the capacity of a server or a client machine in a client-server network environment, or as a peer machine in a peer-to-peer (or distributed) network environment. The data processing system may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that data processing system. Further, while only a single data processing system is illustrated, the term “data processing system” shall also be taken to include any collection of data processing systems that individually or jointly execute a set (or multiple sets) of instructions to perform any one or more of the methodologies described herein. The exemplary data processing system 1200 includes a processor 1202, a main memory 1204 (e.g., read-only memory (ROM), flash memory, dynamic random access memory (DRAM) such as synchronous DRAM (SDRAM) or Rambus DRAM (RDRAM), etc.), a static memory 1206 (e.g., flash memory, static random access memory (SRAM), etc.), and a secondary memory 1218 (e.g., a data storage device), which communicate with each other via a bus 1230.

Processor 1202 represents one or more general-purpose processing devices such as a microprocessor, central processing unit, or the like. More particularly, the processor 1202 may be a complex instruction set computing (CISC) microprocessor, reduced instruction set computing (RISC) microprocessor, very long instruction word (VLIW) microprocessor, processor implementing other instruction sets, or processors implementing a combination of instruction sets. Processor 1202 may also be one or more special-purpose processing devices such as an application specific integrated circuit (ASIC), a field programmable gate array (FPGA), a digital signal processor (DSP), network processor, or the like. Processor 1202 is configured to execute the processing logic 1226 for performing the operations described herein.

The computer system 1200 may further include a network interface device 1208. The computer system 1200 also may include a video display unit 1210 (e.g., a liquid crystal display (LCD), a light emitting diode display (LED), or a cathode ray tube (CRT)), an alphanumeric input device 1212 (e.g., a keyboard), a cursor control device 1214 (e.g., a mouse), and a signal generation device 1216 (e.g., a speaker).

The secondary memory 1218 may include a machine-accessible storage medium (or more specifically a computer-readable storage medium) 1231 on which is stored one or more sets of instructions (e.g., software 1222) embodying any one or more of the methodologies or functions described herein. The software 1222 may also reside, completely or at least partially, within the main memory 1204 and/or within the processor 1202 during execution thereof by the computer system 1200, the main memory 1204 and the processor 1202 also constituting machine-readable storage media. The software 1222 may further be transmitted or received over a network 1220 via the network interface device 1208.

While the machine-accessible storage medium 1231 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies of the present invention. The term “machine-readable storage medium” shall accordingly be taken to include, but not be limited to, solid-state memories, and optical and magnetic media.

In the foregoing specification, embodiments of the invention have been described with reference to specific exemplary embodiments thereof. It will be evident that various modifications may be made thereto without departing from the broader spirit and scope of embodiments of the invention as set forth in the following claims. The specification and drawings are, accordingly, to be regarded in an illustrative sense rather than a restrictive sense.

What is claimed is:

1. A method to fabricate a getter reticle, the method comprising:
depositing a first electrode layer on an insulating substrate;
depositing a first getter layer on the first electrode layer on the insulating substrate, wherein the first electrode layer is configured to provide a first electrode to hold charges in the first getter layer positioned between the first electrode and a second electrode.

2. The method of claim 1, wherein the first electrode layer has a sheet resistance that does not exceed 10⁴ Ohm/sq.

3. The method of claim 1, wherein the first electrode layer is deposited onto a first side of the substrate, and wherein the method further comprises
depositing an optically dark layer in a reflection mode or in a transmission mode on a second side of the substrate.

4. The method of claim 1, wherein the first electrode layer is deposited onto a first side of the substrate, and wherein the method further comprises
depositing one or more optically reflective films on a second side of the substrate.

5. The method of claim 1, wherein the first getter layer includes a porous polymer layer.

6. The method of claim 1, further comprising
depositing a second electrode layer on a second side of the substrate; and
depositing a second getter layer on the second electrode layer, wherein the second electrode layer is configured to provide a third electrode to hold charges in the getter layer positioned between the third electrode and the second electrode.

7. An apparatus, comprising:
a getter reticle comprising
a first electrode layer on an insulating substrate;
an adhesion layer on the first electrode layer; and
a first getter layer on the adhesion layer on the first electrode layer on the insulating substrate.

8. The apparatus of claim 7, wherein the first electrode layer is configured to hold charges in the first getter layer when the first getter layer is positioned between the first electrode and a second electrode.

9. The apparatus of claim 7, wherein the first electrode layer has a sheet resistance that does not exceed 10⁴ Ohm/sq.

10. The apparatus of claim 7, wherein the first electrode layer is adjacent to a first side of the substrate, and wherein the apparatus further comprises
an optically dark layer in a reflection mode or in a transmission mode adjacent to a second side of the substrate.

11. The apparatus of claim 7, wherein the first electrode layer is adjacent to a first side of the substrate, and wherein the apparatus further comprises one or more optically reflective films on a second side of the substrate.

12. The apparatus of claim 7, further comprising
a second electrode layer on a second side of the substrate; and
a second getter layer on the second electrode layer, wherein the second electrode layer is configured to provide a third electrode to hold charges in the getter layer positioned between the third electrode and the second electrode.

13. The apparatus of claim 7, wherein the first getter layer includes a porous polymer layer.

14. The apparatus of claim 7, further comprising
an adhesion layer between the first getter layer and the first electrode layer.

15. The apparatus of claim 7, further comprising
an actual reticle having a backside film, wherein the backside film is covered by the getter reticle.

16. A method to in-situ clean a surface, the method comprising:
attaching a getter reticle to the surface by an electrostatic force, wherein the getter reticle comprises a getter layer on an electrode layer on an insulating substrate;
and
transferring contaminants from the surface to the getter layer by the electrostatic force.

17. The method of claim 16, further comprising
detaching the getter reticle from the surface.

18. The method of claim 16, further comprising
applying a voltage to the surface to provide the electrostatic force.

19. The method of claim 16, further comprising
aligning the getter reticle to the surface.

20. The method of claim 16, wherein the removing is performed in-situ.

21. The method of claim 16, wherein the electrode layer is configured to provide a first electrode to hold charges in the getter layer positioned between the first electrode and a second electrode.
